(19) United States
(12) Patent Application Publication
(10) Pub. No.: US 2020/0341037 A1
(43) Pub. Date: Oct. 29, 2020

(54) ELECTRICAL ASSEMBLY AND METHOD

(71) Applicant: Lear Corporation, Southfield, MI (US)

(72) Inventors: Ramon Serret, Valls (ES); Jose Gabriel Fernández Bañares, Valls (ES); Carlos Fernández Pueyo, Valls (ES); Antoni Ferré Fàbregas, Valls (ES)

(21) Appl. No.: 16/580,056

(22) Filed: Sep. 24, 2019

Related U.S. Application Data
(63) Continuation-in-part of application No. 16/393,527, filed on Apr. 24, 2019.

(51) Int. Cl. G01R 19/25; G06F 1/30; H02J 1/10

(52) U.S. Cl. CPC G01R 19/2503; H02J 1/102; G06F 1/30

(57) ABSTRACT

An electrical assembly may include a plurality of batteries, a switch assembly including a plurality of switches, one or more loads, a sensor, and an electronic control unit (ECU). A method of operating and electrical assembly may include providing power from at least one of the plurality of batteries to the one or more loads, decoupling a switch from the plurality of batteries and/or the one or more loads, and/or testing, via a simulation unit connected to the ECU, the decoupled switch. Testing may be conducted while the one or more loads are operating. The one or more loads may include an electric motor of a vehicle. Operating the one or more loads may include moving said vehicle via said electric motor while testing the decoupled switch. Testing may include providing at least one of an under-voltage and over-voltage condition to a sensor associated with the decoupled switch.

### CROSS-REFERENCE TO RELATED APPLICATION

This application is a continuation-in-part of and claims the benefit of U.S. patent application Ser. No. 16/393,527, filed on Apr. 24, 2019, the disclosure of which is hereby incorporated by reference in its entirety as though fully set forth herein.

### TECHNICAL FIELD

The present disclosure generally relates to electrical assemblies, including electrical assemblies that may be used in connection with vehicles, such as autonomous vehicles or highly-connected vehicles, and/or that may be configured for testing power supply systems.

### BACKGROUND

This background description is set forth below for the purpose of providing context only. Therefore, any aspect of this background description, to the extent that it does not otherwise qualify as prior art, is neither expressly nor impliedly admitted as prior art against the instant disclosure.

Some electrical assemblies may be relatively complex and/or may not provide sufficient functionality. Some electrical assemblies may not be configured for selectively testing the functionality of switches, sensors, and/or power source, such as in real-time.

There is a desire for solutions/options that minimize or eliminate one or more challenges or shortcomings of electrical assemblies. The foregoing discussion is intended only to illustrate examples of the present field and is not a disavowal of scope.

### SUMMARY

In examples, an electrical assembly may include a plurality of batteries, a switch assembly including a plurality of switches, one or more loads, a sensor, and an electronic control unit (ECU). A method of operating an electrical assembly may include providing power from at least one of the plurality of batteries to the one or more loads, decoupling a switch of the plurality of switches from the plurality of batteries and/or the one or more loads, and/or testing, via (e.g., utilizing) a simulation unit connected to the ECU, the decoupled switch. Testing may be conducted while the one or more loads are operating. The one or more loads may include an electric motor of a vehicle. Operating the one or more loads may include moving said vehicle via said electric motor while testing the decoupled switch. Testing may include providing at least one of an under-voltage and over-voltage condition to a sensor associated with the decoupled switch. The sensor may be configured to sense an output voltage of a first battery of the plurality of batteries. Testing may include generating a simulated malfunction in the electrical assembly to determine functionality of at least one of the decoupled switch and a sensor associated with the decoupled switch.

With examples, testing may include generating a simulated malfunction in the electrical assembly to determine the functionality of at least one of the first switch and the first sensor, the second switch and the second sensor, the third switch and the third sensor, and the fourth switch and the fourth sensor. An ECU may include the simulation unit. The simulation unit may be connected to a sensor associated with the decoupled switch. The sensor may be configured to operate the switch. The simulation unit may be configured to transmit a simulated voltage to the sensor. The one or more loads may include at least two loads. The testing may be conducted while the at least two loads are operating and provided with a redundant power supply via the plurality of batteries and switches of the switch assembly other than the decoupled switch. The ECU may be configured to obtain information relating to the decoupled switch indicating at least one of a status of the decoupled switch and a position of the decoupled switch. Testing may include the ECU determining whether the decoupled switch is safe to test.

In examples, an ECU may be configured to measure a voltage associated with the decoupled switch (i) before decoupling the switch and/or (ii) after decoupling the switch and before sending a simulated signal to the decoupled sensor. An ECU may be configured to measure a current associated with the decoupled switch (i) before decoupling the switch and/or (ii) after decoupling the switch and before sending a simulated signal to the decoupled sensor.

With examples, an electrical assembly may include a switch assembly, a sensor connected to the switch assembly, an electronic control unit (ECU) connected to the switch assembly and the sensor, and/or a simulation unit connected to the switch assembly and the ECU. The ECU may be configured to selectively decouple switches of the switch assembly. The simulation unit may be configured to test the decoupled switches and/or the sensor via sending a simulated signal to the sensor while other switches of the switch assembly provide power to a load for operating said load. The simulated signal may include an under-voltage signal. The simulated signal may include an over-voltage signal. The ECU may be configured to receive and transmit information about a status of the switch assembly. A first switch of the switch assembly may be connected to a first battery. A second switch of the switch assembly may be connected to a second battery. A third switch and/or a fourth switch of the switch assembly may be connected to a third battery.

In examples, the simulation unit may be configured to test the sensor and one of the first switch, the second switch, the third switch, and the fourth switch while at least two other switches of the first switch, the second switch, the third switch, and the fourth switch provide power to a load for operating the load. The sensor may include a first sensor connected to the first switch, a second sensor connected to the second switch, a third sensor connected to the third switch, and/or a fourth sensor connected to the fourth switch. The electrical assembly may include a first state configured for testing the first switch and the first sensor, a second state configured for testing the second switch and the second sensor, and/or a third state for testing either or both of (i) the third switch and the third sensor and (ii) the fourth switch and the fourth sensor.

The foregoing and other aspects, features, details, utilities, and/or advantages of embodiments of the present disclosure will be apparent from reading the following description, and from reviewing the accompanying drawings.

### BRIEF DESCRIPTION OF THE DRAWINGS

FIG. 1 is a schematic generally illustrating an embodiment of an electrical assembly according to teachings of the present disclosure.

FIG. 2 is a schematic generally illustrating an embodiment of an electrical assembly according to teachings of the present disclosure.

FIG. 3 is a schematic generally illustrating an embodiment of an electrical assembly according to teachings of the present disclosure.

FIG. 4 is a schematic generally illustrating an embodiment of an electrical assembly according to teachings of the present disclosure.

FIG. 5 is a schematic generally illustrating an embodiment of an electrical assembly according to teachings of the present disclosure.

FIG. 6 is a schematic generally illustrating an embodiment of an electrical assembly according to teachings of the present disclosure.

FIG. 7 is a schematic generally illustrating an embodiment of an electrical assembly according to teachings of the present disclosure.

FIG. 8 is a schematic generally illustrating an embodiment of an electrical assembly according to teachings of the present disclosure.

FIG. 9 is a flowchart generally illustrating an embodiment of a method of operating an electrical assembly according to teachings of the present disclosure.

FIG. 10 is a flowchart generally illustrating an embodiment of a method of operating of an electrical assembly according to teachings of the present disclosure.

### DETAILED DESCRIPTION

Reference will now be made in detail to embodiments of the present disclosure, examples of which are described herein and illustrated in the accompanying drawings. While the present disclosure will be described in conjunction with embodiments and/or examples, they do not limit the present disclosure to these embodiments and/or examples. On the contrary, the present disclosure covers alternatives, modifications, and equivalents.

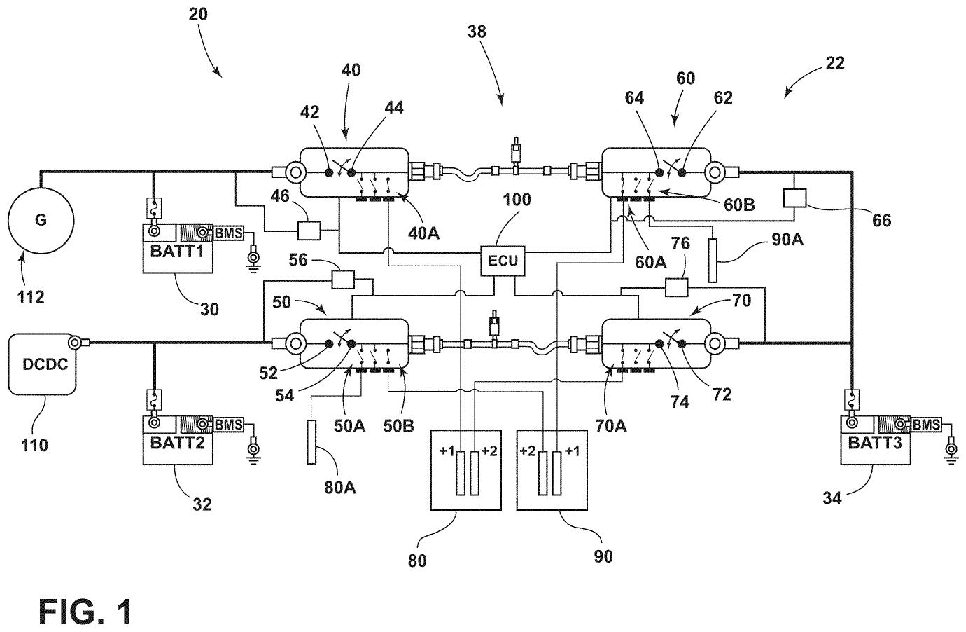

In embodiments, such as generally illustrated in FIG. 1, an electrical assembly 20 may include one or more power sources 30, 32, 34 (e.g., lead-acid batteries, lithium-ion batteries, etc.), and/or a switch assembly 38 that may include one or more switches 40, 50, 60, 70 (e.g., relays, contactors, transistors, MOSFETS, solid state switches, etc.). The electrical assembly 20 may, for example and without limitation, be connected to and/or included with a vehicle 22 (e.g., electric, non-electric, hybrid, etc.). The power sources 30, 32, 34 may be configured as batteries and may be referred to herein as batteries 30, 32, 34, but are not limited to batteries. The electrical assembly 20 may include and/or be configured for connection with one or more electrical loads 80, 80A, 90, 90A. A load (e.g., loads 80, 90) may be configured as a safety-load that may be important and/or critical for operation of the vehicle 22, such as, for example and without limitation, one or more driving motors of a vehicle 22. The electrical loads 80, 90 may include a high level of functional safety and/or the electrical assembly 20 may be configured to provide the loads 80, 90 with supply redundancy. For example, the one or more loads 80, 90 (e.g., electric driving motors) of a vehicle 22 may be redundantly supplied at substantially all times while the vehicle 22 is operated. One or more electrical loads 80, 90 may provide the redundant functionality (e.g., the same or substantially the same function as the other load). For example and without limitation, the loads 80, 90 may be redundant loads and the electrical assembly 20 may provide each with a redundant supply. The electrical assembly 20 may be connected to and/or incorporated with a vehicle 22, which may be fully or partially electric (e.g., hybrid or full electric). The vehicle 22 may be configured for partial and/or full autonomous driving. The switches 40, 50, 60, 70 may be configured to selectively connect the one or more power sources 30, 32, 34 to provide power to the one or more electrical loads 80, 90 (e.g., electric motors). One or more of the switches 40, 50, 60, 70 may include and/or be connected to one or more secondary switches (e.g., secondary switches 40A, 50A, 50B, 60A, 60B, 70A) that may be configured to switch the electrical loads 80, 80A, 90, 90A on and/or off. The electrical assembly 20 may include an electronic control unit (ECU) 100 that may be configured to control operation of at least some of the one or more switches 40, 50, 60, 70.

With embodiments, the ECU 100 may be configured to check or test the functionality of the batteries 30, 32, 34 and/or the connection of the batteries 30, 32, 34 to the one or more loads 80, 90. The ECU 100 may be configured to verify that the batteries 30, 32, 34 are adequately and/or properly charged, such as via a converter 110 and/or a generator 112. If one or more batteries 30, 32, 34 fails, malfunctions, and/or becomes disconnected, the electrical assembly 20 may be configured to connect to one or more of the other batteries 30, 32, 34 to the one or more loads 80, 90. The one or more batteries 30, 32, 34 may be configured to provide sufficient power for full vehicle operation and control (e.g., propulsion, maneuvering, and/or braking).

In embodiments, the ECU 100 may be configured to monitor (e.g., test, identify, etc.) the status and/or functionality of the switches 40, 50, 60, 70 that may be connected to the batteries 30, 32, 34. The ECU 100 may be configured to periodically determine whether the switches 40, 50, 60, 70 connected to the batteries 30, 32, 34 are functioning properly. The ECU 100 may be configured to monitor the status and/or functionality of other components (e.g., such as wiring, sensors, and/or connectors) in and/or connected to the electrical assembly 20.

With embodiments, the ECU 100 may be configured to disconnect faulty batteries while maintaining connection of at least two other batteries with the loads 80, 90. The electrical assembly 20 may be configured to connect at least two of the batteries 30, 32, 34 to each of the first load 80 and the second load 90 at substantially all times.

With embodiments, such as generally illustrated in FIG. 1, an electrical assembly 20 may include a first battery 30, a second battery 32, and/or a third battery 34. The batteries 30, 32, 34 may be configured to provide power for a vehicle 22 (e.g., an autonomous vehicle that may be configured for highly automated driving or HAD). At least two of the first battery 30, the second battery 32, and/or the third battery 34 may be electrically connected to the loads 80, 90 at all times, at least during normal/intended operation. The one or more switches 40, 50, 60, 70 may be configured for connecting and/or disconnecting the first battery 30, the second battery 32, and/or the third battery 34 from a first load 80 and/or a second load 90. The ECU 100 may be configured to isolate a battery 30, 32, 34 from the rest of the electrical assembly 20 and/or from the loads 80, 90, such as if a battery failure (or other failure between the loads 80, 80A, 90, 90A and the batteries 30, 32, 34) is detected. Upon detecting a single battery failure, the ECU 100 may control the switches 40, 50, 60, 70 to provide power from the remaining two batteries 30, 32, 34 to the loads 80, 90.

In embodiments, the batteries 30, 32, 34 may be connected to any number of loads, such as loads that may be used for highly-autonomous vehicles. For example and without limitation, the batteries 30, 32, 34 may be connected to a first load 80 and/or a second load 90. The first load 80 may be configured to drive one or more wheels of a vehicle 22 and/or the second load 90 may be configured to drive one or more other wheels of the vehicle 22. Additionally or alternatively, the loads 80, 90 may be configured as redundant HAD loads. The electrical assembly 20 may include loads 80A, 90A that may be non-HAD loads and that may be disconnected from the electrical assembly 20 in the event of a malfunction (e.g., to isolate the malfunctioning load from the system). The ECU 100 may be configured to selectively turn on and off the loads 80A, 90A, and/or cause the loads 80A, 90A to operate in low-power modes to reduce the overall quiescent current.

With embodiments, such as generally illustrated in FIG. 1, the electrical assembly 20 may include a first switch 40, a second switch 50, a third switch 60, and/or a fourth switch 70. The first switch 40 may include a first contact 42 and/or a second contact 44. The first contact 42 may be connected to the first battery 30. The second contact 44 may be connected to the first load 80 and/or connected to the second load 90 (e.g., via the third switch 60). The second switch 50 may include a first contact 52 and/or a second contact 54. The first contact 52 may be connected to the second battery 32. The second contact 54 may be connected to the second load 90 and/or connected to the first load 80 (e.g., via the fourth switch 70). The third switch 60 may include a first contact 62 and/or a second contact 64. The first contact 62 may be connected to the third battery 34. The second contact 64 may be connected to the second load 90 and/or connected to the first load 80 (e.g., via the first switch 40). The fourth switch 70 may include a first contact 72 and/or a second contact 74. The first contact 72 may be connected to the third battery 34. The second contact 74 may be connected to the first load 80 and/or connected to the second load 90 (e.g., via the third switch 60). The first contact 62 of the third switch 60, the first contact 72 of the fourth switch 70, and the third battery 34 may all be connected such that the third battery 34 may be connected to the first load 80 and/or the second load 90. The second contact 44 of the first switch 40 may be electrically connected with the second contact 64 of the third switch 60, and/or the second contact 54 of the second switch 50 may be electrically connected with the second contact 74 of the fourth switch 70.

In embodiments, such as generally illustrated in FIG. 1, an electrical assembly 20 may be configured to electrically connect at least two batteries 30, 32, 34 to each of the first load 80 and/or the second load 90. The switches 40, 50, 60, 70 may connect at least two of the first battery 30, the second battery 32, and/or the third battery 34 to each of the first load 80 and/or the second load 90. For example and without limitation, the switches 40, 50, 60, 70 may be configured to connect at least two batteries 30, 32, 34 to each of the first load 80 and the second load 90 at all times. The first switch 40 may selectively connect the first battery 30 to the first load 80 and/or the second load 90, and/or the second switch 50 may selectively connect the second battery 32 to the first load 80 and/or second load 90. The third switch 60 and/or the fourth switch 70 may selectively connect the third battery 34 to the first load 80 and/or the second load 90.

In embodiments, such as generally illustrated in FIG. 1, the electrical assembly 20 may be configured to sense (e.g., monitor, detect, measure, etc.) a voltage and/or a current at or near the first switch 40, the second switch 50, the third switch 60, and/or the fourth switch 70, such as via one or more sensors, such as a first sensor 46, a second sensor 56, a third sensor 66, and/or a fourth sensor 76. For example and without limitation, the first sensor 46, the second sensor 56, the third sensor 66, and/or the fourth sensor 76 may include voltage and/or current sensors. The first sensor 46 may be connected to the ECU 100, the first switch 40, and/or the first battery 30. The second sensor 56 may be connected to the ECU 100, the second switch 50, and/or the second battery 32. The third sensor 66 may be connected to the ECU 100, the third switch 60, and/or the third battery 34. The fourth sensor 76 may be connected to the ECU 100, the fourth switch 70, and/or the third battery 34. One or more of the sensors 46, 56, 66, 76 may be configured to facilitate a quick reaction (e.g., opening of a switch, shutting down components, etc.) if an anomaly is detected in/with any node/component connected to the one or more sensors 46, 56, 66, 76).

With embodiments, the first sensor 46, the second sensor 56, the third sensor 66, and/or the fourth sensor 76 may, for example, be configured to sense the voltage at the first contact 42 of the first switch 40, the first contact 52 of the second switch 50, the first contact 62 of the third switch 60, and/or the first contact 72 of the fourth switch 70, respectively. The first sensor 46 may be configured to sense the voltage of the first battery 30, the second sensor 56 may be configured to sense the voltage of the second battery 32, the third sensor 66 may be configured to sense the voltage of the third battery 34, and/or the fourth sensor 76 may be configured to sense the voltage of the third battery 34.

With embodiments, an ECU 100 may be configured to test the operation and/or functionality of connecting the batteries 30, 32, 34 to loads 80, 90. The functionality of the batteries 30, 32, 34 may be verified in real-time by one or more battery monitoring system/sensor (BMS) devices, and/or opening one of the switches 40, 50, 60, 70 may provide a time period with open voltage to perform specific testing. The ECU 100 may be configured to test the functionality (e.g., latent failures) of the first switch 40, the second switch 50, the third switch 60, and/or the fourth switch 70 while at least two batteries 30, 32, 34 are electrically connected to the first load 80 and the second load 90. The functionality of the switches 40, 50, 60, 70 may be tested by operation (e.g., by attempting to actuate the switch) to disconnect and/or connect the batteries 30, 32, 34 while the loads 80, 90 are operating, such as while the vehicle 22 is operating and/or when charging the batteries 30, 32, 34. The ECU 100 may test the switches 40, 50, 60, 70 by measuring the voltage difference between two contacts and/or a specific signal may be generated at a first contact 42, 52, 62, 72 and the same signal verified at a second contact 44, 54, 64, 74.

With embodiments, an electrical assembly 20 may include a first state, a second state, and/or a third state that may each correspond to a respective open and/or closed combination of the first switch 40, the second switch 50, the third switch 60, and/or the fourth switch 70. For example and without limitation, the electrical assembly 20 may test the functionality/operation of the first switch 40 (e.g., disconnecting and/or reconnecting the first battery 30) while the third switch 60 may connect the third battery 34 to the first load 80 and/or the second load 90. The electrical assembly 20 may test the functionality/operation of the second switch 50 (e.g., disconnecting and/or reconnecting the second battery 32) while the fourth switch 70 may connect the third battery 34 to the first load 80 and/or the second load 90. The electrical assembly 20 may test the functionality/operation of the third switch 60 (e.g., disconnecting and/or reconnecting the third battery 34) while the first switch 40 may connect the first battery 30 to the first load 80 and/or the second load 90. The electrical assembly 20 may test the functionality/operation of the fourth switch 70 (e.g., disconnecting and/or reconnecting the third battery 34) while the second switch 50 may connect the second battery 32 to the first load 80 and/or the second load 90.

In embodiments, an electrical assembly 20 may include an ECU 100 that may be connected to the first switch 40, the second switch 50, the third switch 60, and/or the fourth switch 70. The ECU 100 may be configured to control the operation of the first switch 40, the second switch 50, the third switch 60, and/or the fourth switch 70. The ECU 100 may be configured to receive and/or transmit information about the functionality/operation of the first switch 40, the second switch 50, the third switch 60, and/or the fourth switch 70. For example and without limitation, if the ECU 100 detects a failure in the first battery 30 and/or the first switch 40, the ECU 100 may open the first switch 40 and/or close the third switch 60 (e.g., the ECU 100 may disconnect the first battery 30 from the first load 80 and/or the second load 90 and connect the third battery 34 to the first load 80 and/or the second load 90). If the ECU 100 detects a failure in the second battery 32 and/or the second switch 50, the ECU 100 may open the second switch 50 and/or close the fourth switch 70 (e.g., the ECU 100 may disconnect the second battery 32 from the first load 80 and/or the second load 90 and connect the third battery 34 to the first load 80 and/or the second load 90). If the ECU 100 detects a failure in the third battery 34, the third switch 60, and/or the fourth switch 70, the ECU 100 may open the third switch 60 and/or the fourth switch 70, and the ECU 100 may close the first switch 40 and/or the second switch 50 to electrically disconnect the third battery 34 from the vehicle 22 and connect the first battery 30 and the second battery 32 to the loads 80, 90.

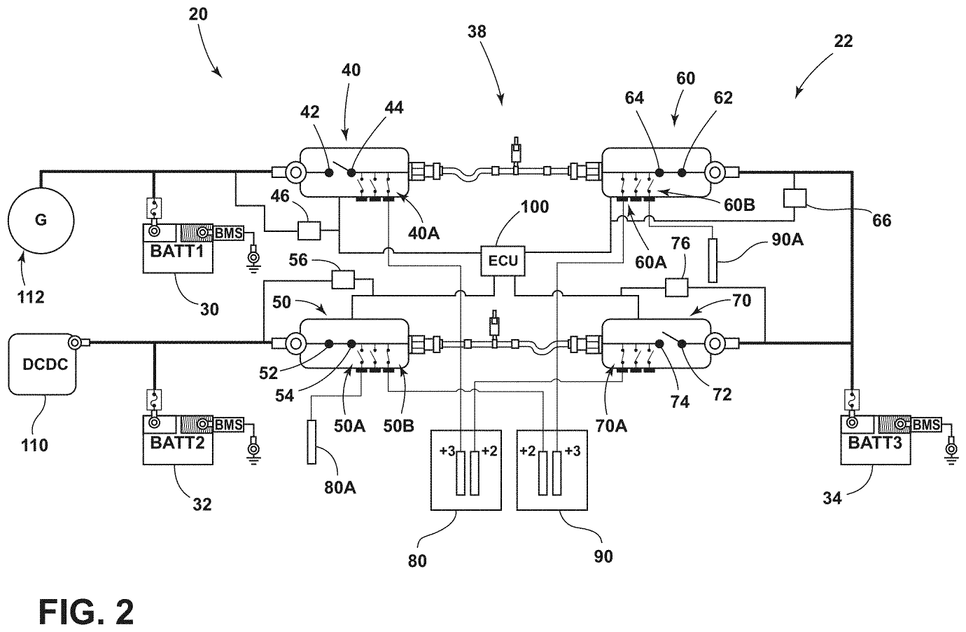

In embodiments, such as generally illustrated in FIG. 2, an electrical assembly 20 may have a first state. When the electrical assembly 20 is in the first state, the functionality/operation of the first switch 40 and/or the first battery 30 may be tested. In the first state, the second switch 50 may be closed, the second switch 50 may electrically connect the second battery 32 to the first load 80 and/or the second load 90, the third switch 60 may be closed, and/or the third switch 60 may connect the third battery 34 to the first load 80 and/or the second load 90. In the first state, the first switch 40 may be opened and/or closed without materially affecting the supply of power to the loads 80, 90, as the loads 80, 90 may remain electrically connected to at least the second battery 32 and the third battery 34 via the second switch 50 and/or the third switch 60 (e.g., the first switch 40 may be decoupled from the electrical assembly 20, at least temporarily, such as via the ECU 100). When the electrical assembly 20 is in the first state, the fourth switch 70 may be open such that the third battery 34 may be connected to the first load 80 and/or the second load 90 via the third switch 60 and not the fourth switch 70. In the first state, the functionality/operation of the first switch 40, a first sensor 46, and/or the first battery 30 may be determined/tested without compromising the safety of the electrical assembly 20 (e.g., while maintaining the redundant supply to the loads 80, 90). For example and without limitation, the ECU 100 may open and/or close the first switch 40 one or more times to determine if the first switch 40 and/or the first battery 30 is working properly.

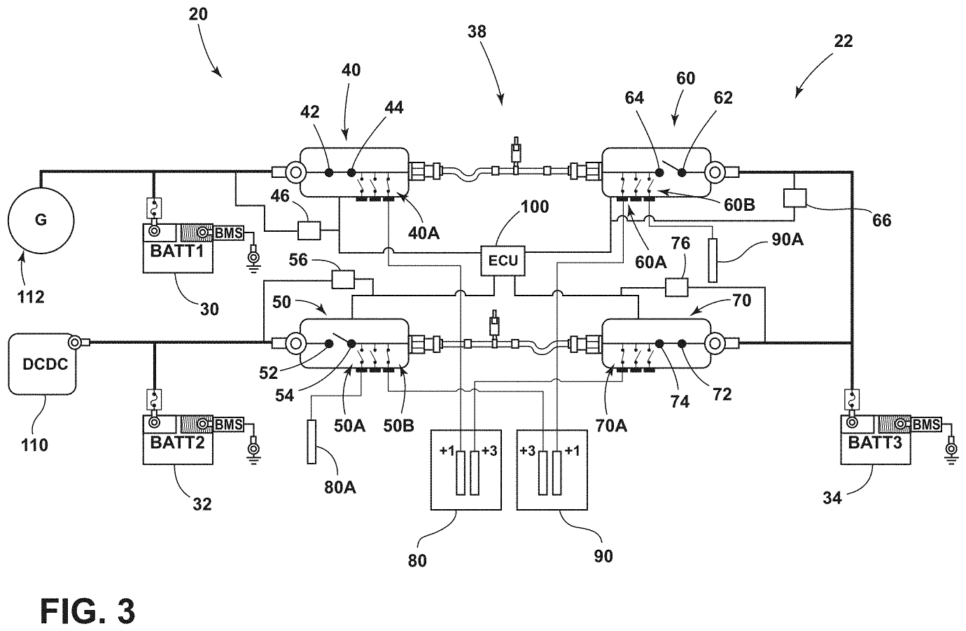

With embodiments, such as generally illustrated in FIG. 3, the electrical assembly 20 may have a second state. When the electrical assembly 20 is in the second state, the functionality/operation of the second switch 50, a second sensor 56, and/or the second battery 32 may be tested. The first switch 40 may be closed, and/or the first switch 40 may electrically connect the first battery 30 to the first load 80 and/or the second load 90. In the second state, the fourth switch 70 may be closed, and/or the fourth switch 70 may electrically connect the third battery 34 to the first load 80 and/or the second load 90. When the electrical assembly 20 is in the second state, the third switch 60 may be open such that the third battery 34 be connected to the loads 80, 90 via the fourth switch 70 and not the third switch 60. The second switch 50 may be opened and/or closed without materially affecting the supply of power to the loads 80, 90, as the loads 80, 90 may remain electrically connected to at least the first battery 30 and the third battery 34 via the first switch 40 and/or the fourth switch 70.

In the second state, the functionality/operation of the second switch 50, the second sensor 56, and/or the second battery 32 may be determined/tested without compromising the safety of the electrical assembly 20, such as while maintaining the redundant supply to the loads 80, 90 (e.g., the second switch 50 may be at least temporarily electrically decoupled from the electrical assembly 20, such as via the ECU 100). For example and without limitation, the ECU 100 may open and/or close the second switch 50 one or more times to determine if the second switch 50 and/or the second battery 32 is working properly.

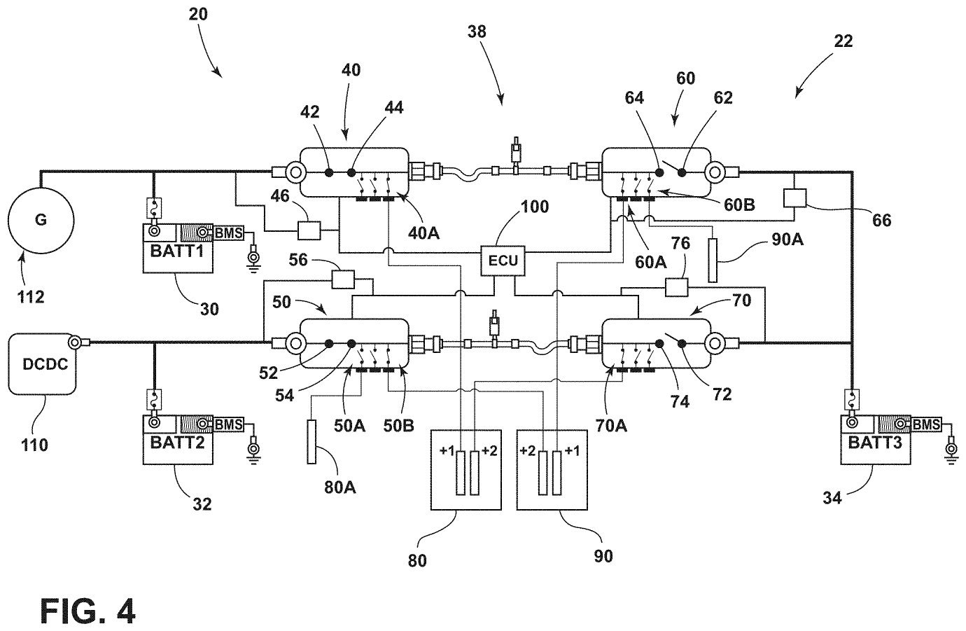

In embodiments, such as generally illustrated in FIGS. 4, 5 and 6, an electrical assembly 20 may include a third state that may correspond to normal operation. When the electrical assembly 20 is in the third state, the functionality/operation of the third switch 60 and/or the fourth switch 70 may be tested. The third switch 60 and/or the fourth switch 70 may be opened and/or closed without interfering with the first battery 30 and/or the second battery 32, such that the first load 80 and the second load 90 may be electrically connected to the first battery 30 and the second battery 32 regardless of the open/closed status of the third switch 60 or the fourth switch 70 (e.g., the third switch 60 and/or the fourth switch 70 may be electrically decoupled from the electrical assembly 20, at least temporarily, such as by the ECU 100). In the third state, the first switch 40 may be closed, and/or the first switch 40 may electrically connect the first battery 30 to the first load 80 and/or the second load 90. Additionally or alternatively, when the electrical assembly 20 is in the third state, the second switch 50 may be closed, and/or the second switch 50 may electrically connect the second battery 32 to the first load 80 and/or the second load 90. In the third state, such as generally illustrated in FIGS. 4-6, both of the first battery 30 and the second battery 32 may be connected to each of the first load 80 and the second load 90 (e.g., such that either or both of the third switch 60 and the fourth switch 70 may be tested while maintaining the redundant supply to the loads 80, 90).

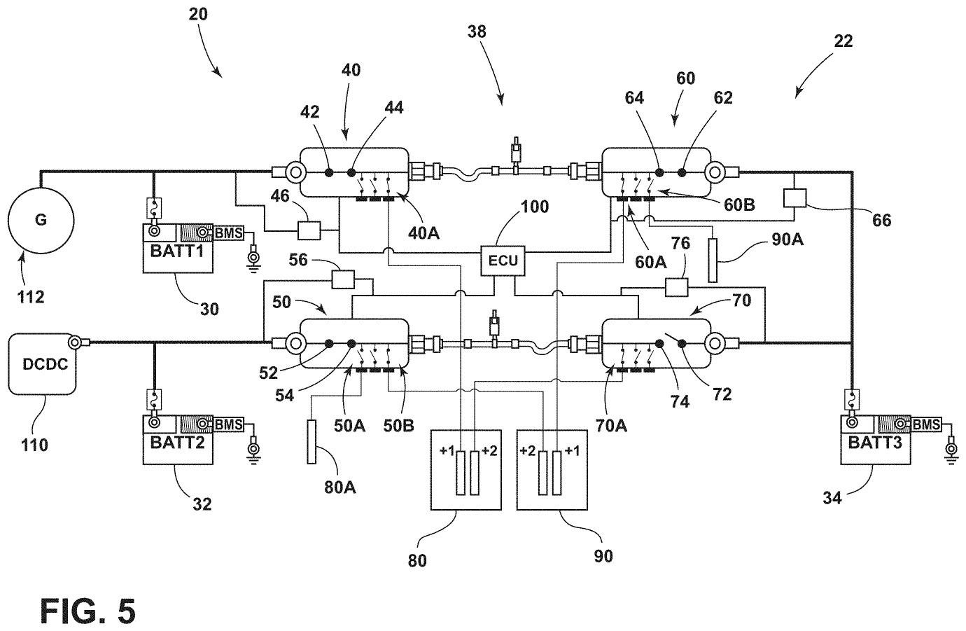

With embodiments, such as generally illustrated in FIG. 5, the functionality/operation of the third switch 60 may be tested in the third state of the electrical assembly 20. The third switch 60 may be opened and/or closed (e.g., via the ECU 100, a third sensor 66, and/or a fourth sensor 76) while the fourth switch 70 may be open when the electrical assembly 20 is in the third state without materially affecting the supply of power to the first load 80 or the second load 90. For example and without limitation, in the third state, the first battery 30 may be electrically connected to the first load 80 and the second load 90, and the second battery 32 may be electrically connected to the first load 80 and the second load 90, so closing and/or opening the third switch 60 may not disconnect either of the first battery 30 or the second battery 32 from either of the loads 80, 90.

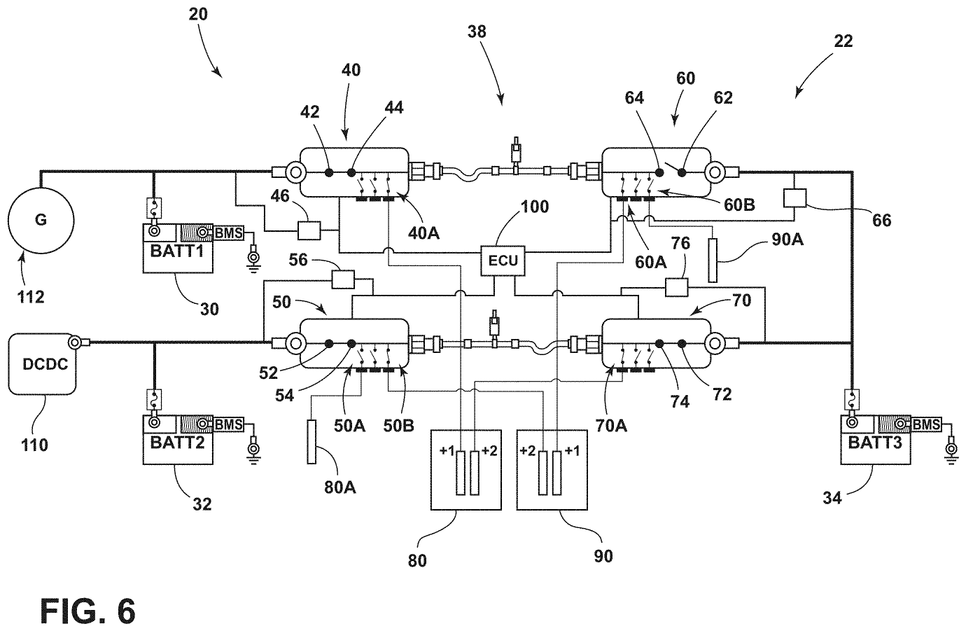

In embodiments, such as generally illustrated in FIG. 6, the functionality/operation of the fourth switch 70 may be tested in the third state of the electrical assembly 20. The fourth switch 70 may be opened and/or closed while the third switch 60 may be open when the electrical assembly 20 is in the third state without materially affecting the supply of power to the first load 80 or the second load 90. For example and without limitation, in the third state, the first battery 30 may be electrically connected to the first load 80 and the second load 90, and the second battery 32 may be electrically connected to the first load 80 and the second load 90, so closing and/or opening the fourth switch 70 may not disconnect either of the first battery 30 or the second battery 32 from either of the loads 80, 90.

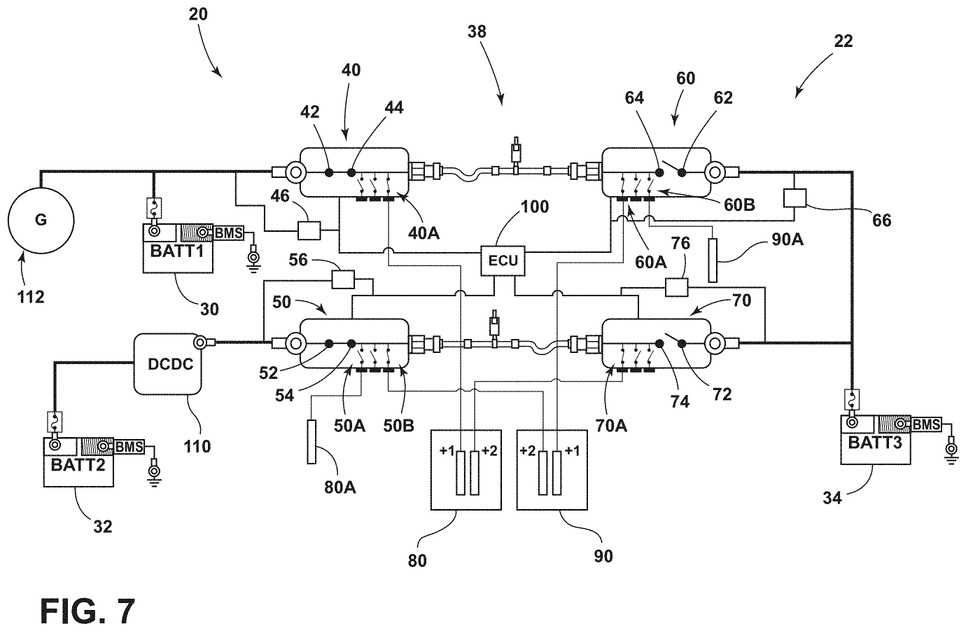

With embodiments, such as generally illustrated in FIG. 7, the electrical assembly 20 may include a converter 110 that may be connected to a battery (e.g., the second battery 32). The converter 110 may include a DC/DC converter that may increase or decrease the voltage of the second battery 32 (e.g., at the first contact 52 of the second switch 50). The resulting voltage at the second switch 50 may be substantially the same as voltages at the first switch 40, the third switch 60, and/or the fourth switch 70.

In embodiments, one or more of the batteries 30, 32, 34 may provide a voltage different from at least one other battery. For example and without limitation, the voltage of the second battery 32 may include, but is not be limited to, 24V, 48V, or larger voltages (e.g., hundreds of volts), or smaller voltages.

In embodiments, a method of operating an electrical assembly 20 may include providing a first battery 30, a second battery 32, and/or a third battery 34. The method may include providing a first switch 40, a second switch 50, a third switch 60, and/or a fourth switch 70. The method may include providing a first load 80 and/or a second load 90. The method may include selectively opening and/or closing the first switch 40, the second switch 50, the third switch 60, and/or the fourth switch 70 wherein at least two of the batteries 30, 32, 34 may be connected to the first load 80 and/or the second load 90 at all or substantially all times. The method may include opening the first switch 40 to disconnect the first battery 30 from the first load 80 and the second load 90, connecting the third battery 34 to the first load 80 and the second load 90, testing the first switch 40, and/or transmitting information relating to a status of the first switch 40 to an ECU 100 (see, e.g., FIG. 2). The method may include opening the second switch 50 to disconnect the second battery 32 from the first load 80 and the second load 90, connecting the third battery 34 to the first load 80 and the second load 90, testing the second switch 50, and/or transmitting information relating to a status of the second switch 50 to an ECU 100 (see, e.g., FIG. 3). The method may include opening either or both of the third switch 60 and the fourth switch 70, connecting the first battery 30 to the first load 80 and the second load 90, connecting the second battery 32 to the first load 80 and the second load 90, testing the third switch 60 and/or the fourth switch 70, and/or transmitting information relating to a status of the third switch 60 and/or the fourth switch 70 to an ECU 100 (see, e.g., FIGS. 4-6).

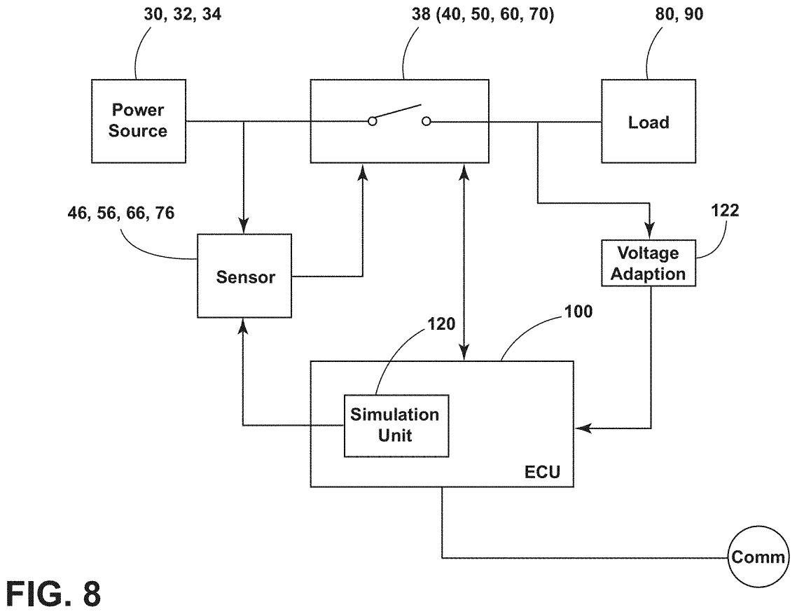

With embodiments, such as generally illustrated in FIG. 8, an electrical assembly 20 may be configured to sense a voltage at or near a switch of a switch assembly 38, such as at or near the first switch 40, the second switch 50, the third switch 60, and/or the fourth switch 70 via the first sensor 46, the second sensor 56, the third sensor 66, and/or the fourth sensor 76, respectively. The first sensor 46, the second sensor 56, the third sensor 66, and/or the fourth sensor 76 may be connected to the ECU 100 such that the sensors 46, 56, 66, 76 may provide information (e.g., voltage information) to the ECU 100 and/or the ECU 100 may obtain information from the sensors 46, 56, 66, 76. The first sensor 46, the second sensor 56, the third sensor 66, and/or the fourth sensor 76 may be configured to detect an under-voltage condition and/or an over-voltage of the first battery 30, the second battery 32, and/or the third battery 34. In embodiments, the ECU 100 may receive information from the sensors 46, 56, 66, 76 and/or the ECU 100 may be configured to determine whether the first battery 30, the second battery 32, and/or the third battery 34 is supplying an under-voltage and/or an over-voltage to the switches 40, 50, 60, 70. The ECU 100 may, for example, disconnect a battery 30, 32, 34 that is supplying under-voltage and/or over-voltage, such as via controlling the switch assembly 38 to open a respective switch or switches 40, 50, 60, 70. Additionally or alternatively, the ECU 100 may receive voltage information (e.g., directly), such as at the second contact 44, 54, 64, 74 and via a voltage adaption circuit 122. The ECU 100 utilizing such direct voltage information, compared to the one or more sensors 46, 56, 66, 76 sensing the voltage, may result in a slower reaction time to a detected error. Such direct voltage information may, for example be utilized for testing purposes.

In embodiments, such as generally illustrated in FIG. 8, an ECU 100 of an electrical assembly 20 may be connected to and/or include a simulation unit 120. The simulation unit 120 may be configured to simulate one or more electrical characteristics and/or signals. The ECU 100 may be configured to control the simulation unit 120. For example and without limitation, the simulation unit 120 may be configured to simulate (e.g., generate) an under-voltage signal and/or an over-voltage signal. The simulation unit 120 may be electrically connected (e.g., physically and/or wirelessly) to the first sensor 46, the second sensor 56, the third sensor 66, and/or the fourth sensor 76. The simulation unit 120 may be configured to transmit a simulated signal (e.g., under-voltage and/or over-voltage) to the first sensor 46, the second sensor 56, the third sensor 66, and/or the fourth sensor 76.

With embodiments, the ECU 100 may be configured to test the functionality of one or more switches 40, 50, 60, 70 and/or one or more sensors 46, 56, 66, 76. The ECU 100 may be configured to decouple a respective switch 40, 50, 60, 70, sensor 46, 56, 66, 76, and/or battery 30, 32, 34 prior to testing. For example and without limitation, the ECU 100 may transition the electrical assembly 20 to the first state, which may include at least temporarily/partially electrically decoupling the first switch 40, the first sensor 46, and/or the first battery 30 from the electrical assembly 20, to test the first switch 40 and the first sensor 46. The ECU 100 may transition the electrical assembly 20 to the second state, which may include at least temporarily/partially electrically decoupling the second switch 50, the second sensor 56, and/or the second battery 32 from the electrical assembly 20, to test the second switch 50 and the second sensor 56. The ECU 100 may transition the electrical assembly 20 to the third state, which may include at least temporarily/partially electrically decoupling the third switch 60, the third sensor 66, the fourth switch 70, the fourth sensor 76, and/or the third battery 34 from the electrical assembly 20, to test the third switch 60, the third sensor 66, the fourth switch 70, and/or the fourth sensor 76.

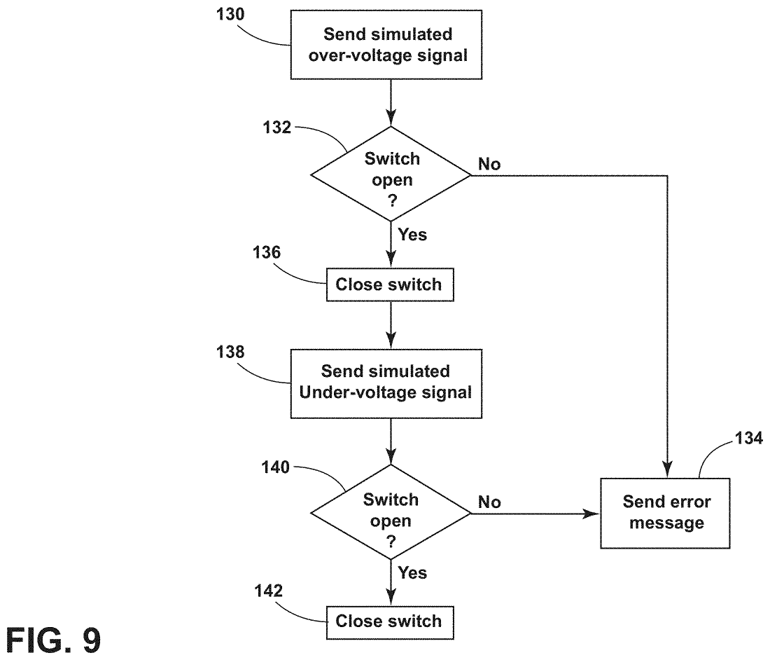

In embodiments, testing may be configured to determine whether a switch (e.g., a switch 40, 50, 60, 70) and/or a corresponding sensor (e.g., a sensor 46, 56, 66, 76), such as a decoupled switch and sensor, are functioning properly. As generally illustrated in FIG. 9, testing may include the simulation unit 120 generating a first test signal and transmitting the first test signal to a decoupled sensor (step 130). The first test signal may be configured to simulate a condition that should cause the sensor to open the switch (e.g., under-voltage from a power source/battery). The ECU 100 may be configured to monitor the switch to determine if the switch opens after the first test signal is transmitted to the sensor (step 132). If the switch does not open, the ECU 100 may determine that an error has occurred and/or generate/transmit an error message (e.g., a controller area network or CAN message), such as via a communication bus (e.g., a CAN bus) (step 134). Additionally or alternatively, the ECU 100 may at least temporarily suspend use of the malfunctioning switch. If the switch opens, the ECU 100 may continue testing and/or may close the switch (step 136).

With embodiments, continuing testing may include the simulation unit 120 generating a second test signal and transmitting the second test signal to the decoupled sensor (step 138). The second test signal may be configured to simulate a condition (e.g., over-voltage from a power source/battery) that should cause the sensor to open the switch. The ECU 100 may be configured to monitor the switch to determine if the switch opens after the second test signal is transmitted to the sensor (step 140), which may include comparing information from a sensor with direction voltage information from a voltage adaption circuit 122. If the switch does not open, the ECU 100 may determine that an error has occurred and/or generate/transmit an error message (e.g., a CAN message), such as via a communication bus (e.g., a CAN bus) (step 134). Additionally or alternatively, the ECU 100 may at least temporarily suspend use of the malfunctioning switch, sensor, and/or battery. If the switch opens, the ECU 100 may close the switch and/or complete testing of the switch/sensor (step 142). Once testing of a switch/sensor is complete, the ECU 100 may begin testing another switch/sensor.

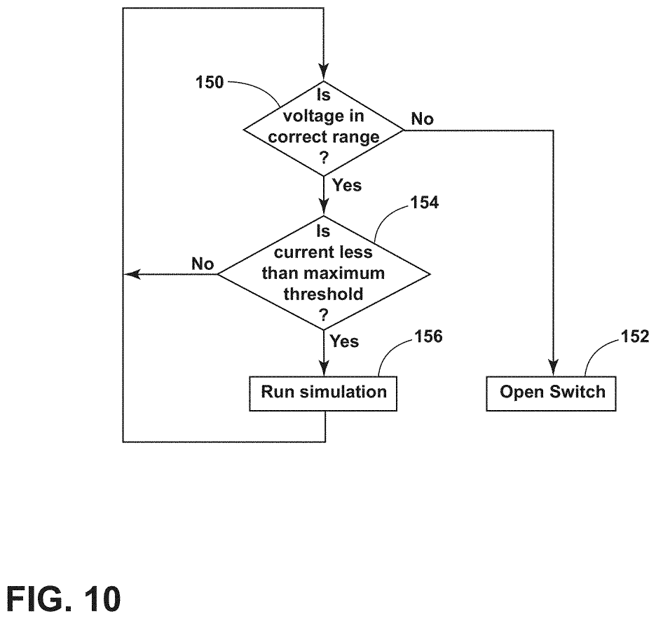

With embodiments, such as generally illustrated in FIG. 10, an ECU 100 may be configured to determine a voltage and/or a current associated with the first switch 40, the second switch 50, the third switch 60, and/or the fourth switch 70. The ECU 100 may be configured to test the functionality of the switches 40, 50, 60, 70 if the ECU 100 first determines that the electrical assembly 20 (e.g., the specific switch 40, 50, 60, 70) is safe to connect and/or disconnect. The ECU 100 may obtain the voltage at or near a switch 40, 50, 60, 70 and determine whether the voltage is below a maximum voltage and/or above a minimum voltage for safe operation (step 150). If the voltage of the switch 40, 50, 60, 70 is not between the maximum voltage and the minimum voltage, the ECU 100 may open the switch to disconnect the corresponding battery 30, 32, 34 (step 152). If the voltage is in the desired range, the ECU 100 may further determine whether the current flowing through the switch 40, 50, 60, 70 is less than a maximum current threshold (step 154). If the voltage is less than the maximum voltage, the voltage is greater than the minimum voltage, and the current is less than the maximum current, then the ECU 100 may determine that corresponding portions of the electrical assembly 20 are safe to test and may decouple (e.g., temporarily) and test the corresponding switch 40, 50, 60, 70, sensor 46, 56, 66, 76, and/or battery 30, 32, 34 periodically (step 156).

Embodiments of an electrical assembly 20 may include fewer power sources/batteries and/or fewer switches than other designs. For example and without limitation, the electrical assembly 20 may provide redundancy for two batteries (e.g., the first and second batteries 30, 32) with one battery (e.g., the third battery 34).

In embodiments, an ECU 100 may be configured to automatically (e.g., without user intervention) test switches 40, 50, 60, 70 of the switch assembly 38, sensors 46, 56, 66, 76, the batteries 30, 32, 34 and/or other wiring/connector elements contained within and/or connected to the electrical assembly 20. If a switch 40, 50, 60, 70, sensor 46, 56, 66, 76, or a battery 30, 32, 34 connected thereto fails a test (e.g., malfunctions, becomes disconnected, etc.), the ECU 100 may be configured to automatically disconnect the malfunctioning section of the electrical assembly 20.

With embodiments, testing may be conducted in real-time without materially affecting power provided to the loads 80, 90. For example and without limitation, in the event a component fails a test, the ECU 100 may be configured to automatically and/or immediately disconnect that component and connect a back-up or redundant component to maintain providing power to the loads 80, 90. Additionally or alternatively, testing may be conducted, at least in part, while the loads 80, 90 are operating, such as driving a vehicle 22, and may not require taking the loads 80, 90 offline or putting the loads 80, 90 in a testing mode that may have reduced functionality.

Embodiments of an electrical assembly 20 may be compatible with Levels 1-5 HAD, and/or may comply with ASIL D metrics, for example and without limitation.

In embodiments, an electronic control unit (e.g., ECU 100) may include an electronic processor, such as a programmable microprocessor and/or microcontroller. In embodiments, an ECU may include, for example, an application specific integrated circuit (ASIC). An ECU may include a central processing unit (CPU), a memory (e.g., a non-transitory computer-readable storage medium), and/or an input/output (I/O) interface. An ECU may be configured to perform various functions, including those described in greater detail herein, with appropriate programming instructions and/or code embodied in software, hardware, and/or other medium. In embodiments, an ECU may include a plurality of controllers. In embodiments, an ECU may be connected to a display, such as a touchscreen display.

Various embodiments are described herein for various apparatuses, systems, and/or methods. Numerous specific details are set forth to provide a thorough understanding of the overall structure, function, manufacture, and use of the embodiments as described in the specification and illustrated in the accompanying drawings. It will be understood by those skilled in the art, however, that the embodiments may be practiced without such specific details. In other instances, well-known operations, components, and elements have not been described in detail so as not to obscure the embodiments described in the specification. Those of ordinary skill in the art will understand that the embodiments described and illustrated herein are non-limiting examples, and thus it can be appreciated that the specific structural and functional details disclosed herein may be representative and do not necessarily limit the scope of the embodiments.

Reference throughout the specification to “various embodiments,” “with embodiments,” “in embodiments,” or “an embodiment,” or the like, means that a particular feature, structure, or characteristic described in connection with the embodiment is included in at least one embodiment. Thus, appearances of the phrases “in various embodiments,” “with embodiments,” “in embodiments,” or “an embodiment,” or the like, in places throughout the specification are not necessarily all referring to the same embodiment. Furthermore, the particular features, structures, or characteristics may be combined in any suitable manner in one or more embodiments. Thus, the particular features, structures, or characteristics illustrated or described in connection with one embodiment/example may be combined, in whole or in part, with the features, structures, functions, and/or characteristics of one or more other embodiments/examples without limitation given that such combination is not illogical or non-functional. Moreover, many modifications may be made to adapt a particular situation or material to the teachings of the present disclosure without departing from the scope thereof.

It should be understood that references to a single element are not necessarily so limited and may include one or more of such element. Any directional references (e.g., plus, minus, upper, lower, upward, downward, left, right, leftward, rightward, top, bottom, above, below, vertical, horizontal, clockwise, and counterclockwise) are only used for identification purposes to aid the reader's understanding of the present disclosure, and do not create limitations, particularly as to the position, orientation, or use of embodiments.

Joinder references (e.g., attached, coupled, connected, and the like) are to be construed broadly and may include intermediate members between a connection of elements and relative movement between elements. As such, joinder references do not necessarily imply that two elements are directly connected/coupled and in fixed relation to each other. The use of “e.g.” in the specification is to be construed broadly and is used to provide non-limiting examples of embodiments of the disclosure, and the disclosure is not limited to such examples. Uses of “and” and “or” are to be construed broadly (e.g., to be treated as “and/or”). For example and without limitation, uses of “and” do not necessarily require all elements or features listed, and uses of “or” are intended to be inclusive unless such a construction would be illogical.

While processes, systems, and methods may be described herein in connection with one or more steps in a particular sequence, it should be understood that such methods may be practiced with the steps in a different order, with certain steps performed simultaneously, with additional steps, and/or with certain described steps omitted.

It is intended that all matter contained in the above description or shown in the accompanying drawings shall be interpreted as illustrative only and not limiting. Changes in detail or structure may be made without departing from the present disclosure.

It should be understood that a controller (e.g., controller), a system, and/or a processor as described herein may include a conventional processing apparatus known in the art, which may be capable of executing preprogrammed instructions stored in an associated memory, all performing in accordance with the functionality described herein. To the extent that the methods described herein are embodied in software, the resulting software can be stored in an associated memory and can also constitute means for performing such methods. Such a system or processor may further be of the type having both ROM, RAM, a combination of non-volatile and volatile memory so that any software may be stored and yet allow storage and processing of dynamically produced data and/or signals.

It should be further understood that an article of manufacture in accordance with this disclosure may include a non-transitory computer-readable storage medium having a computer program encoded thereon for implementing logic and other functionality described herein. The computer program may include code to perform one or more of the methods disclosed herein. Such embodiments may be configured to execute one or more processors, multiple processors that are integrated into a single system or are distributed over and connected together through a communications network, and/or where the network may be wired or wireless. Code for implementing one or more of the features described in connection with one or more embodiments may, when executed by a processor, cause a plurality of transistors to change from a first state to a second state. A specific pattern of change (e.g., which transistors change state and which transistors do not), may be dictated, at least partially, by the logic and/or code.

What is claimed is:

1. A method of operating an electrical assembly including a plurality of batteries, a switch assembly including a plurality of switches, one or more loads, and an electronic control unit (ECU), the method comprising:
providing power from at least one of the plurality of batteries to the one or more loads;
decoupling a switch of the plurality of switches from the plurality of batteries and/or the one or more loads; and
testing, via a simulation unit connected to the ECU, the decoupled switch;
wherein the testing is conducted while the one or more loads are operating.

2. The method of claim 1, wherein the one or more loads include an electric motor of a vehicle and operating the one or more loads includes moving said vehicle via said electric motor while testing the decoupled switch.

3. The method of claim 1, wherein the testing includes providing at least one of an under-voltage and over-voltage condition to a sensor associated with the decoupled switch.

4. The method of claim 3, wherein the sensor is configured to sense an output voltage of a first battery of the plurality of batteries.

5. The method of claim 1, wherein the testing includes generating a simulated malfunction in the electrical assembly to determine functionality of at least one of the decoupled switch and a sensor associated with the decoupled switch.

6. The method of claim 1, wherein the electrical assembly includes a first sensor connected to and configured to operate a first switch of the plurality of switches, a second sensor connected to and configured to operate a second switch of the plurality of switches, a third sensor connected to and configured to operate a third switch of the plurality of switches, and a fourth sensor connected to and configured to operate a fourth switch of the plurality of switches.

7. The method of claim 1, wherein the ECU includes the simulation unit; the simulation unit is connected to a sensor associated with the switch; and the sensor is configured to operate the switch.

8. The method of claim 7, wherein the simulation unit is configured to transmit a simulated voltage to the sensor.

9. The method of claim 1, wherein the one or more loads includes at least two loads; and the testing is conducted while the at least two loads are operating and provided with a redundant power supply via the plurality of batteries and switches of the switch assembly other than the decoupled switch.

10. The method of claim 1, the ECU is configured to obtain information relating to the decoupled switch indicating at least one of a status of the decoupled switch and a position of the decoupled switch.

11. The method of claim 1, wherein the testing includes the ECU determining whether the decoupled switch is safe to test.

12. The method of claim 1, wherein the ECU is configured to measure a voltage associated with the decoupled switch (i) before decoupling the decoupled switch and (ii) after decoupling the decoupled switch and before sending a simulated signal to a sensor connected to the decoupled switch.

13. The method of claim 1, wherein the ECU is configured to measure a current associated with the decoupled switch (i) before decoupling the decoupled switch and (ii) after decoupling the decoupled switch and before sending a simulated signal to a sensor connected to the decoupled switch.

14. An electrical assembly, comprising:
a switch assembly;
a sensor connected to the switch assembly;
an electronic control unit (ECU) connected to the switch assembly and the sensor; and
a simulation unit connected to the switch assembly and the ECU;
wherein the ECU is configured to selectively decouple switches of the switch assembly; and the simulation unit is configured to test the decoupled switches and/or the sensor via sending a simulated signal to the sensor while other switches of the switch assembly provide power to a load for operating said load.

15. The electrical assembly of claim 14, wherein the simulated signal includes an under-voltage signal.

16. The electrical assembly of claim 14, wherein the simulated signal includes an over-voltage signal.

17. The electrical assembly of claim 14, wherein the ECU is configured to receive and transmit information about a status of the switch assembly.

18. The electrical assembly of claim 14, wherein a first switch of the switch assembly is connected to a first battery, a second switch of the switch assembly is connected to a second battery, and a third switch and a fourth switch of the switch assembly are connected to a third battery.

19. The electrical assembly of claim 18, wherein the simulation unit is configured to test the sensor and one of the first switch, the second switch, the third switch, and the fourth switch while at least two other switches of the first switch, the second switch, the third switch, and the fourth switch provide power to said load for operating said load.

20. The electrical assembly of claim 18, wherein the sensor includes a first sensor connected to the first switch, a second sensor connected to the second switch, a third sensor connected to the third switch, and a fourth sensor connected to the fourth switch; and the electrical assembly includes a first state configured for testing the first switch and the first sensor, a second state configured for testing the second switch and the second sensor, and a third state for testing either or both of (i) the third switch and the third sensor and (ii) the fourth switch and the fourth sensor.
